(19) United States
(12) Patent Application Publication
(10) Pub. No.: US 2026/0136976 A1
(43) Pub. Date: May 14, 2026

(54) MECHANICAL SUBSTRATE WITH MATCHED COEFFICIENT OF THERMAL EXPANSION

(71) Applicant: Analog Power Conversion LLC, Bend, OR (US)

(72) Inventors: Wang-Chang A. GU, Bend, OR (US); Su-Wen CHEN, Bend, OR (US); Dumitru Gheorge SDRULLA, Bend, OR (US); Amaury GENDRON, Bend, OR (US)

(21) Appl. No.: 18/941,357

(22) Filed: Nov. 8, 2024

(51) Int. Cl. H01L 23/15; H01L 23/00; H01L 23/498

(52) U.S. Cl. CPC H10W 70/692; H10W 70/658; H10W 90/401; H10W 42/121; H10W 72/536; H10W 72/877; H10W 72/884; H10W 90/724; H10W 90/734; H10W 90/754

(57) ABSTRACT

A semiconductor device comprises a first substrate and a semiconductor die mechanically coupled to the first substrate. The coefficient of linear thermal expansion (CTE) of the first substrate is similar to the CTE of the semiconductor die. The substrate may comprise single-crystal 4H silicon carbide. One or more insulating layers may be disposed over the first substrate. A second substrate may be disposed adjacent to a side of the semiconductor die opposite the side the first substrate is disposed adjacent to. One or more terminals may be disposed over a first surface of the first substrate, one or more backside terminals may be disposed over a second surface of the first substrate opposite the first surface, and the one or more terminals may be respectively electrically coupled to the one or more backside terminals through the first substrate.

### BACKGROUND

Semiconductor dies (hereinafter dies) may be mounted to a substrate. The substrate may provide physical support, carry off heat generated by the dies, and in some cases provide electrical insulation to the semiconductor device.

Over time, dies have grown larger, on-die and ambient operating temperatures of dies have increased, the size of interconnects to the die have decreased, and a maximum number of interconnects to the dies have increased.

A die mounted on a substrate may experience a wide range of temperatures over its operating lifetime. For example, the die and substrate may thermal cycle between 25° C. when an apparatus is off or idle, and 180° C. or more when that apparatus is fully on.

As a result, substrates known in the art that have substantially different Coefficients of linear Thermal Expansion (CTEs) relative to the die may decrease the life expectancy of the die. For example, when the CTE of a substrate is substantially different from a die having potentially thousands of small connection points such as solder bumps, and the substrate and die thermal cycle over a large temperature range, the difference in the respective changes in dimensions of the die and the substrate may cause the solder bumps to deform, break, or short together, which may lead to the die becoming non-operational.

In the past, substrates having CTE different from dies mounted thereon have conventionally been used because the conditions (such as noted above) under which such CTE mismatches could cause device failure were relatively rare. For example, substrates made of Aluminum Nitride (AlN) or Silicon Nitride (Si₃N₄) are commonly used even though they have poor thermal conductivity and, in the case of AlN, a CTE substantially different from common semiconductor dies.

However, as the conditions under which mismatched CTEs can cause damage become increasingly commonplace, more situations may arise where such substrates may not be suitable.

Many materials with CTEs similar to a die may be unsuitable for use as a substrate because they do not possess the necessary insulating properties, lack the needed thermal conductivity, are fragile, are subject to corrosion in the target operating environment, or are too expensive.

Accordingly, it would be advantageous to have a substrate suitable for use in applications that experience thermal cycling over a wide range of temperatures that would prevent temperature-induced mechanical stress from damaging a die mounted on that substrate while also possessing the desired physical and electrical properties for the application.

### SUMMARY OF THE INVENTION

Embodiments relate to semiconductor packaging, and in particular to substrates used to mechanically support semiconductor device dies where the substrates are primarily made of a CTE-matched material such as single-crystal 4H Silicon Carbide (SiC).

In an embodiments, a semiconductor device comprises a first substrate and a semiconductor die mechanically coupled to the first substrate. The coefficient of linear thermal expansion (CTE) of the first substrate is similar to the CTE of the semiconductor die.

In embodiments, two CTEs are considered similar when a difference between the two CTEs is 10% or less over an entire target operating temperature range of the semiconductor device. In other embodiments, two CTEs are considered similar when a difference between the two CTEs is 0.30×10−6/° C. or less over an operating temperature range of the semiconductor device.

In embodiments, the substrate comprises single-crystal 4H silicon carbide.

In an embodiment, one or more insulating layers are disposed over the first substrate.

In an embodiment, a second substrate is disposed adjacent to a side of the semiconductor die opposite the side of the semiconductor die adjacent to the first substrate. The semiconductor die is mechanically coupled to the second substrate, and a CTE of the second substrate is similar to the CTE of the semiconductor die.

In an embodiment, one or more terminals are disposed over a first surface of the first substrate, one or more backside terminals are disposed over a second surface of the first substrate opposite the first surface, and the one or more terminals may be respectively electrically coupled to the one or more backside terminals.

### BRIEF DESCRIPTION OF THE DRAWINGS

FIG. 1A is a cross section of an apparatus for mechanically supporting a die using a substrate according to an embodiment.

FIG. 1B is a cross section of an apparatus for mechanically supporting a die using a substrate according to another embodiment.

FIG. 2A is a cross section of an apparatus for mechanically supporting a die using a substrate according to another embodiment.

FIG. 2B is a cross section of an apparatus for mechanically supporting a die using a substrate according to another embodiment.

FIG. 3A is a cross section of an apparatus for mechanically supporting a die using substrates according to an embodiment.

FIG. 3B is a cross section of an apparatus for mechanically supporting a die using substrates according to another embodiment.

FIG. 4A is a cross section of an apparatus for mechanically supporting a die using a substrate according to another embodiment.

FIG. 4B is a cross section of an apparatus for mechanically supporting a die using a substrate according to another embodiment.

FIG. 4C is a cross section of an apparatus for mechanically supporting a die using a substrate according to another embodiment.

FIG. 4D is a cross section of an apparatus for mechanically supporting a die using a substrate according to another embodiment.

FIG. 4E is a cross section of an apparatus for mechanically supporting a die using a substrate according to another embodiment.

FIG. 4F is a cross section of an apparatus for mechanically supporting a die using a substrate according to another embodiment.

FIG. 4G is a cross section of an apparatus for mechanically supporting a die using a substrate according to another embodiment.

FIG. 4H is a cross section of an apparatus for mechanically supporting a die using a substrate according to another embodiment.

FIG. 5A is a cross section of an apparatus for mechanically supporting a die using substrates according to an embodiment.

FIG. 5B is a cross section of an apparatus for mechanically supporting a die using substrates according to another embodiment.

FIG. 5C is a cross section of an apparatus for mechanically supporting a die using substrates according to an embodiment.

### DETAILED DESCRIPTION

Embodiments of the present application relate to substrates on to which one or more dies may be mounted for mechanical support. In particular, embodiments relate to substrates having a Coefficient of linear Thermal Expansion (CTE) substantially similar to the one or more die mounted thereon. The bulk of such a substrate may comprise single-crystal 4H Silicon Carbide (SIC).

A detailed description of embodiments is provided below along with accompanying figures. The scope of this disclosure is limited only by the claims and encompasses numerous alternatives, modifications, and equivalents. Although steps of various processes may be presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

The illustrated embodiments describe substrates that support a single die having three electrical connection points (e.g., pads), but embodiments are not limited thereto, and a person of ordinary skill in the art would understand that one or more other kinds of die may be mounted to substrates according to embodiments.

In the descriptions of the embodiments, the part making up the bulk of a substrate may be referred to as the “substrate”, but a person of ordinary skill in the related arts would understand that “substrate” may also include additional elements (such as insulating layers, conductive elements, protective coatings, and the like) disposed on or in the bulk of the substrate.

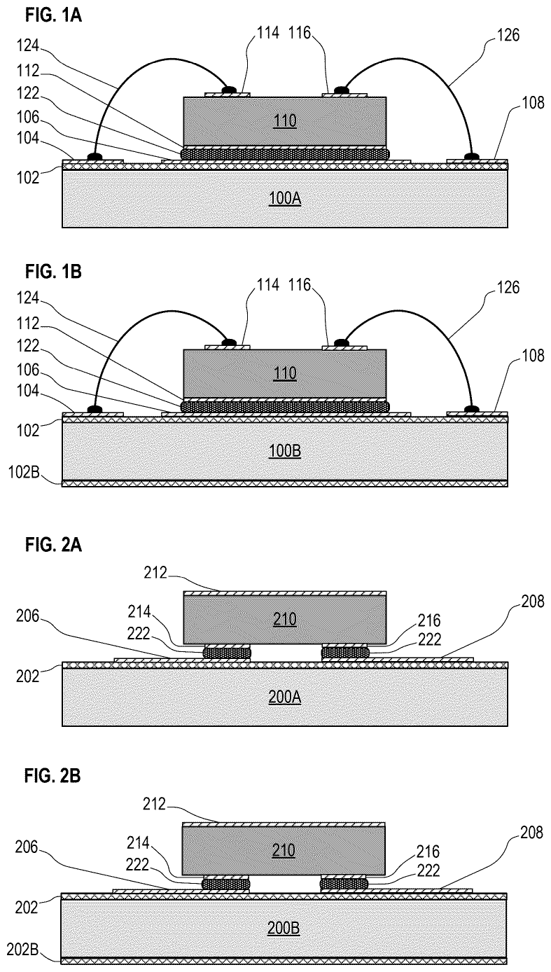

FIG. 1A illustrates an apparatus for mechanically supporting a die 110 using a substrate 100A providing mechanical support for a die 110 according to an embodiment. The bulk of the substrate 100A may comprise single-crystal 4H SiC.

In the illustrated embodiment, the die 110 may be a SiC Vertical Metal Oxide Semiconductor Field Effect Transistor (V_MOSFET), and accordingly, the die 110 includes a drain pad 112 disposed on a bottom of the die 110 and a gate pad 114 and a source pad 116 disposed on a top of the die 110. However, embodiments are not limited thereto, and may include one or more dies having different devices therein and/or made of different semiconductor materials (such as silicon).

The composition and structure of the drain pad 112, gate pad 114, and source pad 116 may be as is known in the related arts. Collectively, structures such as the drain pad 112, the gate pad 116, the source pad 116, and the like are referred to herein as pads.

The substrate 100A includes an insulating layer 102 disposed on top of the substrate 100A, and a gate terminal 104, drain terminal 106, and a source terminal 108 each disposed on the insulating layer 102. These terminals may be used to electrically connect the die 110 to circuits not shown in FIG. 1A. Collectively these and other similar structures disposed on the substrate may be referred to as terminals.

The insulating layer 102 may be used when the substrate 100A may not provide sufficient electrical insulation. The insulating layer 102 may comprise aluminum nitride (AlN) or other materials known in the art to be suitable therefor. In embodiments, the insulating layer 102 may be between 5 and 50 microns thick.

The die 110 is mechanically affixed to the substrate 100A by solder 122 disposed between and adhering to the drain terminal 106 and the drain pad 112. The solder 122 also provides an electrical connection between the drain terminal 106 and the drain pad 112.

A first bond wire 124 electrically connects the gate terminal 104 to the gate pad 114. A second bond wire 126 electrically connects the source terminal 108 to the source pad 116.

If the CTE of the substrate 100A were substantially different from the CTE of the die 110, then a large temperature change to one or both of the substrate 100A and the die 110 could impose mechanical stresses on the solder 122 that could lead to device failure.

However, the single-crystal 4H SiC that makes up the bulk of the substrate 100A has a CTE of 2.74×10⁻⁶/° C. at 12° C. and of 4.28×10⁻⁶/° C. at 376° C., which is similar to the CTEs of materials commonly used in dies 110 such as SiC, silicon (Si) (CTE=2.49×10⁻⁶/° C. at 25° C. and 3.61×10⁻⁶/° C. at 227° C.) and Gallium Nitride (GaN) (CTE=3.17×10⁻⁶/° C.).

Accordingly, because the substrate 100A is comprised of single-crystal 4H SiC, failures due to mechanical stresses arising from a CTE mismatch may be prevented.

The CTE of a substrate may be considered matched to the CTE of the die when the two CTEs differ by less than 10% over the entirety of a temperature range of interest, such as the temperature swing of a thermal cycle of a target application. Alternatively, the CTE of a substrate may be considered matched to the CTE of the die when the two CTEs differ by less than 0.30×10⁻⁶/° C. over the entirety of the temperature range of interest.

FIG. 1B illustrates an apparatus for mechanically supporting a die 110 using a substrate 100B according to another embodiment.

The substrate 100B differs from the substrate 100A of FIG. 1A in that a second insulating layer 102B is disposed on the bottom of the substrate 100B. The second insulating layer 102B may comprise the same materials as the insulating layer 102 or may comprise a different material.

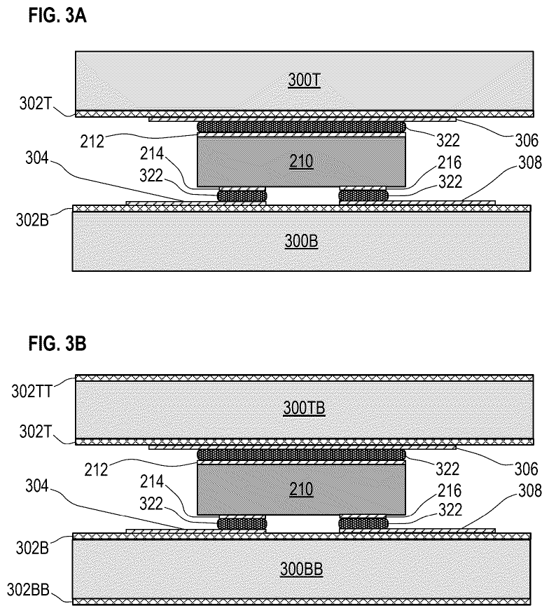

FIG. 2A illustrates an apparatus for mechanically supporting a die 210 using a substrate 200A according to another embodiment.

The die 210 differs from the die 110 of FIG. 1A by being inverted. Accordingly, the die 210 comprises a drain pad 212 disposed on a top of the die 210 and a gate pad 214 and a source pad 216 disposed on a bottom of the die 210.

The substrate 200A includes an insulating layer 202 disposed on top of the substrate 200A, and a gate terminal 206 and a source terminal 208 each disposed on the insulating layer 202. These terminals along with the drain pad 212 may be used to electrically connect the die 210 to circuits not shown in FIG. 2A.

The die 210 is mechanically affixed to the substrate 200A by solder 222 disposed both between and adhering to the gate terminal 206 and the gate pad 214 and between and adhering to the source terminal 208 and the source pad 216. The solder 222 also provides an electrical connection between the terminals and the pads.

If the CTE of the substrate 200A were substantially different from the CTE of the die 210, then a large temperature change to one or both of the substrate 200A and the die 210 could cause a dislocation of the relative positions of the terminals 206 and 208 and the corresponding pads 214 and 216, which would impose mechanical stress on the solder 222 that could lead to device failure. However, the single-crystal 4H SiC that makes up the bulk of the substrate 200A has a CTE similar to the CTEs of materials commonly used in dies 210, reducing that dislocation to a negligible value.

FIG. 2B illustrates an apparatus for mechanically supporting a die 210 using a substrate 200B according to another embodiment.

The substrate 200B differs from the substrate 200A of FIG. 2A in that a second insulating layer 202B is disposed on the bottom of the substrate 200B. The second insulating layer 202B may comprise the same materials as the insulating layer 202 or may comprise a different material.

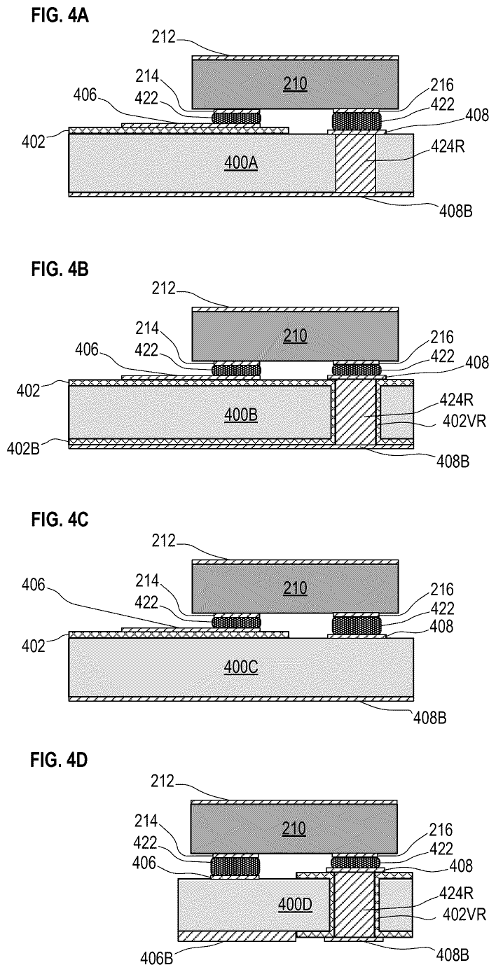

FIG. 3A illustrates an apparatus for mechanically supporting a die using top and bottom substrates 300T and 300B according to an embodiment.

The top substrate 300T includes an insulating layer 302T disposed on the bottom, and a drain terminal 306 disposed on the insulating layer 302T which may be used to electrically connect the die 210 to circuits not shown in FIG. 3A.

The bottom substrate 300B includes an insulating layer 302B disposed on top of the substrate 300B, and a gate terminal 304 and a source terminal 308 each disposed on the insulating layer 300B. These terminals may be used to electrically connect the die 210 to circuits not shown in FIG. 3A.

The die 210 is mechanically affixed to the bottom substrate 300B by solder 322 disposed both between and adhering to the gate terminal 304 and the gate pad 214 and between and adhering to the source terminal 308 and the source pad 216. The solder 322 also provides an electrical connection between these terminals and pads.

The die 210 is mechanically affixed to the top substrate 300T by solder 322 disposed between and adhering to the drain terminal 306 and the drain pad 212. The solder 322 also provides an electrical connection between the drain terminal 306 and the drain pad 212.

If the CTE of the top substrate 300T, the bottom substrate 300B, or both were substantially different from the CTE of the die 210, then a large temperature change to the substrates, the die 210, or both could cause a dislocation of the relative positions of the terminals and the corresponding pads, which would impose mechanical stress on the solder 322 that could lead to device failure. However, the single-crystal 4H SiC that makes up the bulk of the substrate 300B has a CTE similar to the CTEs of materials commonly used in dies 210, thus preventing that dislocation.

FIG. 3B illustrates an apparatus for mechanically supporting a die 210 using top and bottom substrates 300 TB and 300BB according to an embodiment.

The top substrate 300 TB differs from the top substrate 300T of FIG. 3A by having a second insulating layer 302TT on the top of the top substrate 300 TB. The second insulating layer 302TT may comprise the same materials as the insulating layer 302T or may comprise a different material.

The bottom substrate 300BB differs from the bottom substrate 300B of FIG. 3A by having a second insulating layer 302BB on the bottom of the bottom substrate 300BB. The second insulating layer 302BB may comprise the same materials as the insulating layer 302B or may comprise a different material.

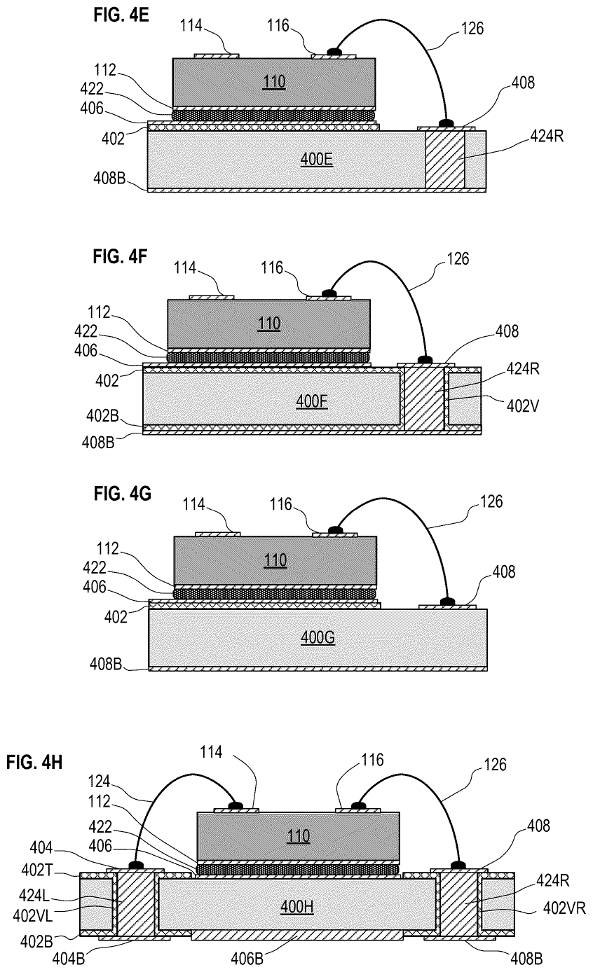

FIG. 4A illustrates an apparatus for mechanically supporting a die 210 using a substrate 400A according to another embodiment.

The substrate 400A is similar to the substrate 200A of FIG. 2A in having an insulating layer 402, a gate terminal 406, and a source terminal 408 disposed on the top of the substrate 400A. Solder 422 is disposed in a manner similar to the solder 222 does in FIG. 2A and performs the same functions.

The substrate 400A differs from the substrate 200A of FIG. 2A in that the source terminal 408 is not mounted on the insulating layer 402, a sinker 424R (which may also be referred to as a through-substrate via) is disposed in the substrate 400A, and a bottom source terminal 408B is disposed on a bottom of the substrate 400A.

The sinker 424R electrically couples the source terminal 408 to the bottom source terminal 408B. Accordingly, the bottom source terminal 408B may be used to electrically connect the source pad 216 of the die 210 to external circuits not shown in FIG. 4A. The sinker 424R may be comprised of conductive materials such as are known in the art as being suitable therefor.

The bulk of the substrate 400A may have a low electrical conductivity such that no insulation is required between the sinker 424R and the bulk of the substrate 400A.

FIG. 4B illustrates an apparatus for mechanically supporting a die 210 using a substrate 400B according to another embodiment.

The substrate 400B differs from the substrate 400A of FIG. 4A in that the sinker 424R is isolated from the bulk of the substrate 400B by an insulating layer 402VR, the source terminal 408 is isolated from the bulk of the substrate 400B by the insulating layer 402, and the bottom source terminal 408B is isolated from the bulk of the substrate 400B by a bottom insulating layer 402B disposed on the bottom of the substrate 400B.

FIG. 4C illustrates an apparatus for mechanically supporting a die 210 using a substrate 400C according to another embodiment.

The substrate 400C differs from the substrate 400A of FIG. 4A in that there is no sinker in the substrate 400C. Instead, the bulk of the substrate 400C is doped to be highly conductive, so that the bulk of the substrate 400C electrically couples the source terminal 408 to the bottom source terminal 408B.

FIG. 4D illustrates an apparatus for mechanically supporting a die 210 using a substrate 400D according to another embodiment.

The substrate 400D combines features of the substrate 400B of FIG. 4B and the substrate 400C of FIG. 4C. Specifically, the bulk of the substrate 400D is heavily doped to be highly conductive as in FIG. 4C and the substrate 400D incorporates a sinker 424R electrically insulated from the bulk of the substrate 400D by an insulating layer 402VR to electrically couple the source terminal 408 to the bottom source terminal 408B.

Furthermore, a bottom gate terminal 406B is disposed on the bottom of the substrate 400D and electrically coupled to the gate terminal 406 through the highly-conductive bulk of the substrate 400D.

FIG. 4E illustrates an apparatus for mechanically supporting a die 110 using a substrate 400E according to another embodiment.

The embodiment of FIG. 4E differs from the embodiment of FIG. 4A in that the die 110 of FIG. 4E is inverted relative to the die 210 of FIG. 4A. Accordingly, similarly to FIG. 1A, the die 110 is mechanically coupled to the substrate 400E by solder 422 disposed between, adhering to, and electrically coupling the drain pad 112 and the drain terminal 406.

Similarly to in FIG. 1A, a bond wire 126 electrically couples the source pad 116 to the source electrode 408.

However, the source electrode 408 is further electrically coupled by a sinker 424R to a bottom source pad 408B disposed on the bottom of the substrate 400E, similarly to as described in FIG. 4A.

FIG. 4F illustrates an apparatus for mechanically supporting a die 110 using a substrate 400F according to another embodiment.

The substrate 400F differs from the substrate 400E in that the sinker 424V and the bottom source pad 408B are insulated from the bulk of the substrate 400F by insulating layers 402V and 402B, as describe with respect to FIG. 4B.

FIG. 4G illustrates an apparatus for mechanically supporting a die 110 using a substrate 400G according to another embodiment.

The substrate 400G differs from the substrate 400E in that the bulk of the substrate 400G is doped to have a low electrical resistance and there is no sinker. Accordingly, the source terminal 408 is electrically coupled to the bottom source terminal 408B by the bulk of the substrate 400G, as described with respect to FIG. 4C.

FIG. 4H illustrates an apparatus for mechanically supporting a die 110 using a substrate 400H according to another embodiment.

In FIG. 4H, the die 110 is electrically and mechanically coupled to the terminals on the top of the substrate 400H as described in FIG. 1A.

However, in FIG. 4H, the terminals on the top are further electrically coupled to terminals on the bottom. That is, a gate terminal 404 is electrically coupled to a bottom gate terminal 404B using an insulated sinker comprising sinker 424L and insulating layer 402VL, such as is described with respect to FIG. 4B, a source terminal 408 is electrically coupled to a bottom source terminal 408B using another such insulated sinker comprising sinker 424R and insulating layer 402VR, and a drain terminal 406 is electrically coupled to a bottom drain terminal 406B using the bulk of the substrate 4H, which has been doped to have a high conductivity, such as is described with reference to the gate terminal 406 and bottom gate terminal 406B of FIG. 4D.

The substrate 400H allows all connections between the die 110 and external circuits to be made on the bottom side of the substrate 400H.

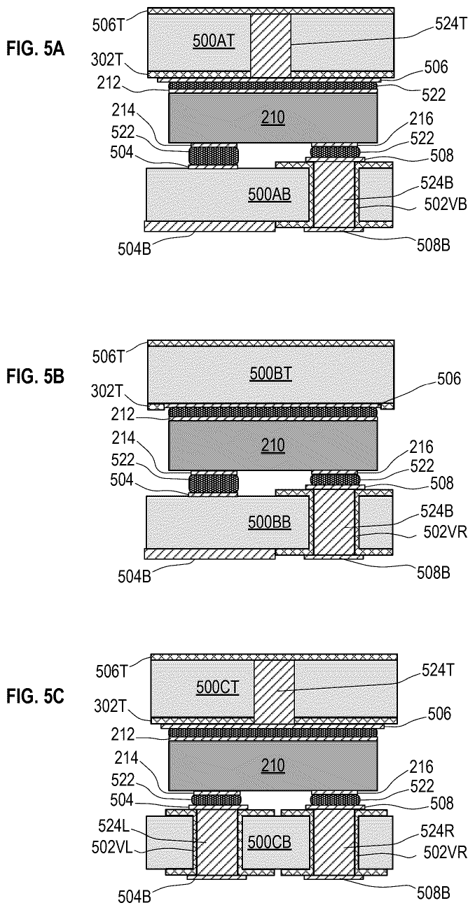

FIGS. 5A through 5C disclose embodiments wherein one or more die may be mounted between two substrates according to an embodiment configured such that all electrical connections to circuits not mounted between the substrates are made through terminals disposed on the outside of the substrate-die(s)-substrate stack. Such embodiments may provide superior environmental protection to the one or more dies mounted therein, and because the substrates have CTEs matched to the dies as described above do not encounter the reliability-reducing temperature-induced mechanical stresses of substrates known in the art.

FIG. 5A illustrates an apparatus for mechanically supporting a die 210 using top and bottom substrates 500AT and 500AB according to an embodiment.

The substrates of FIG. 5A differ from the substrates shown in FIG. 3A in that connections are made between terminals on the die-facing surface of the substrates and backside terminals on opposite surfaces of the substrates.

Accordingly, the top substrate 500AT includes a sinker 524T that electrically couples a drain terminal 506 on the bottom of the top substrate 500AT with a top drain terminal 506T on the top of the top substrate 500AT.

Also, the bulk of the bottom substrate 500AB is doped to be highly conductive and electrically couples the gate terminal 504 on a top of the bottom substrate 500AB to a bottom gate terminal 504B on a bottom of the bottom substrate 500AB.

Finally, an insulated sinker comprising sinker 524B and insulating layer 502VB electrically couples the source terminal 508 on the top of the bottom substrate 500AB to a bottom source terminal 508B on the bottom of the bottom substrate 500AB.

FIG. 5B illustrates an apparatus for mechanically supporting a die 210 using top and bottom substrates 500BT and 500BB according to another embodiment.

The apparatus of FIG. 5B differs from the apparatus of FIG. 5A in that the drain terminal 506 on the bottom of the top substrate 500BT is electrically coupled to the top drain terminal 506T on the top of the top substrate 500AT using the bulk of the top substrate 500BT. To enable this, the bulk of the top substrate 500BT may be doped to have a low resistance.

FIG. 5C illustrates an apparatus for mechanically supporting a die 210 using top and bottom substrates 500CT and 500CB according to an embodiment.

The apparatus of FIG. 5C differs from the apparatus of FIG. 5A in that an insulated sinker comprising sinker 524L and insulating layer 502VL electrically couples the gate terminal 504 on a top of the bottom substrate 500CB to a bottom gate terminal 504B on a bottom of the bottom substrate 500CB. Unlike in the embodiment of FIG. 5A, in the embodiment of FIG. 5C, the bulk of the bottom substrate 500CB need not be doped to have a low resistance.

Embodiments provide reduced mechanical stress to one or more devices (such as dies) mounted on a substrate by having the TCE of the bulk of the substrate match the TCE of the devices mounted thereto.

In embodiments, the substrates may provide electrical insulation to the devices.

In embodiments, the substrates may include terminals for making electrical connections to the devices.

In some embodiments, the resulting apparatus is conducive to the use of low-cost packaging for the embodiment.

In some embodiments, the resulting apparatus is conducive to double sided cooling.

Aspects of the present disclosure have been described in conjunction with the specific embodiments that are presented as illustrative examples, but embodiments are not limited to those shown in the drawings or those mentioned in the accompanying text. Numerous alternatives, modifications, and variations to the disclosed embodiments may be made without departing from the scope of the claims set forth below. Embodiments disclosed herein are not intended to be limiting.

What is claimed is:

1. A semiconductor device comprising:
a first substrate, and
a semiconductor die mechanically coupled to the first substrate,
wherein a coefficient of linear thermal expansion (CTE) of the first substrate is similar to the CTE of the semiconductor die.

2. The semiconductor device of claim 1, wherein two CTEs are considered similar when a difference between the two CTEs is 10% or less over an entire target operating temperature range of the semiconductor device.

3. The semiconductor device of claim 1, wherein two CTEs are considered similar when a difference between the two CTEs is 0.30×10⁻⁶/° C. or less over an operating temperature range of the semiconductor device.

4. The semiconductor device of claim 1, wherein the first substrate comprises single-crystal 4H silicon carbide.

5. The semiconductor device of claim 1,
wherein the semiconductor die comprises one or more pads,
wherein the first substrate comprises one or more terminals, and
wherein the one or more pads are electrically and mechanically coupled to the one or more terminals, respectively.

6. The semiconductor device of claim 5, further comprising:
an insulating layer disposed over the first substrate,
wherein the one or more terminals are disposed over the insulating layer.

7. The semiconductor device of claim 5,
wherein the one or more terminals are disposed over a first surface of the first substrate,
wherein the first substrate comprises a backside terminal disposed over a second surface of the substrate, the second surface being opposite the first surface, and
wherein the backside terminal is electrically coupled to at least one of the one or more terminals.

8. The semiconductor device of claim 7, wherein the backside terminal is electrically coupled to the at least one of the one or more terminals through a sinker disposed in the first substrate.

9. The semiconductor device of claim 8, wherein the sinker is insulated from a portion of the first substrate by at least one insulating layer.

10. The semiconductor device of claim 7,
wherein a portion of the first substrate is doped to have a low resistance, and
wherein the backside terminal is electrically coupled to the at least one of the one or more terminals through the portion of the first substrate.

11. The semiconductor device of claim 5, wherein the one or more pads comprise all the pads of the semiconductor die.

12. The semiconductor device of claim 11,
wherein the one or more terminals are disposed over a first surface of the first substrate
wherein the first substrate comprises one or more backside terminals disposed over a second surface of the first substrate, the second surface being opposite the first surface, and
wherein the one or more terminals are respectively electrically coupled to the one or more backside terminals.

13. The semiconductor device of claim 1, further comprising:
a second substrate,
wherein the first substrate is disposed adjacent to a first side of the semiconductor die,
wherein the second substrate is disposed adjacent to a second side of the semiconductor die, the second side of the semiconductor die being opposite the first side of the semiconductor die,
wherein the semiconductor die is mechanically coupled to the second substrate, and
wherein a coefficient of linear thermal expansion (CTE) of the second substrate is similar to the CTE of the semiconductor die.

14. The semiconductor device of claim 13,
wherein the semiconductor die comprises a first set of one or more pads disposed on the first side and a second set of one or more pads disposed on the second side,
wherein the first substrate comprises a first set of one or more terminals,
wherein the second substrate comprises a second set of one or more terminals,
wherein the first set of one or more pads are electrically and mechanically coupled to the first set of one or more terminals, respectively, and
wherein the second set of one or more pads are electrically and mechanically coupled to the second set of one or more terminals, respectively.

15. The semiconductor device of claim 14,
wherein the first set of one or more terminals are disposed on a first side of the first substrate,
wherein the second set of one or more terminals are disposed on a first side of the second substrate,
wherein the first substrate comprises a first backside terminal disposed on a second side of first substrate opposite the first side of the first substrate and electrically coupled through the first substrate to one of the first set of one or more terminals, and
wherein the second substrate comprises a second backside terminal disposed on a second side of second substrate opposite the first side of the second substrate and electrically coupled through the second substrate to one of the second set of one or more terminals.
